(19) United States
(12) Patent Application Publication
(10) Pub. No.: US 2024/0038429 A1
(43) Pub. Date: Feb. 1, 2024

(54) STACKED MAGNETIC COMPOUND MOLDED INTEGRATED ISOLATION TRANSFORMER

(71) Applicant: Texas Instruments Incorporated, Dallas, TX (US)

(72) Inventors: Yi Yan, San Jose, CA (US); Vivek Arora, San Jose, CA (US)

(21) Appl. No.: 17/873,785

(22) Filed: Jul. 26, 2022

(51) Int. Cl. H01F 17/00; H01F 27/28; H01L 23/48; H01L 23/64

(52) U.S. Cl. CPC H01F 17/0033; H01F 17/0013; H01F 27/2804; H01L 23/481; H01L 23/645; H01F 2027/2809; H01F 2017/0086; H01F 2017/0073; H01F 2017/002

(57) ABSTRACT

An electronic device with an integrated transformer including a first substrate having a first patterned conductive feature with multiple turns that form a first winding, and a first molded magnetic material that encloses a portion of the first patterned conductive feature, and an adhesive layer on a side of the first substrate. The transformer also includes a second substrate having a second patterned conductive feature with multiple turns that form a second winding, and a second molded magnetic material that encloses a portion of the second patterned conductive feature, the second substrate extending on the adhesive layer to magnetically couple the first and second windings. The electronic device includes a package structure that encloses the first and second substrates.

### BACKGROUND

Magnetic circuits, such as transformers, provide a galvanic isolation barrier for isolated power supplies to facilitate high-voltage insulation between primary and secondary circuits. Other circuitry can use transformers for isolating circuits operating at different voltage potentials, including communications circuits. Integrating magnetic materials into packaged electronic devices facilitates system size reduction and increased power density. One approach to integrated magnetic materials is laminate planar transformers with magnetic sheets above and below a laminate winding. However, laminate planar transformer integration requires multiple mount and cure processes and yields a tall stack structure which can undesirably increase package height and cause subsequent package molding problems including trapped air bubbles. In addition, the ac winding loss as well as reduced reliability in laminate transformers is significant due to fringing effects caused by the airgap between two magnetic plates, which limits the power delivery capability through the transformer. Another approach uses an integrated toroid transformer, which has good efficiency due to high permeability of the toroid core, but this approach requires a floating toroid core that can cause difficulties and increase the total device dimensions during packaging. A further approach involves an on-chip integrated transformer, which can be qualified for reinforced isolation and is simple to integrate during device packaging. However, on-chip integrated transformers suffer from low efficiency and higher cost compared with laminate-based planer transformers.

### SUMMARY

In one aspect, an electronic device includes first and second substrates, an adhesive layer, and a package structure that encloses the first and second substrates. The first substrate includes a first patterned conductive feature with multiple turns that form a first winding, and a first molded magnetic material that encloses a portion of the first patterned conductive feature. Then adhesive layer extends on a side of the first substrate. The second substrate includes a second patterned conductive feature with multiple turns that form a second winding, and a second molded magnetic material that encloses a portion of the second patterned conductive feature, the second substrate extending on the adhesive layer to magnetically couple the first and second windings.

In another aspect, a transformer includes a first substrate, a second substrate, and an adhesive layer. The first substrate includes a first patterned conductive feature with multiple turns that form a first winding, and a first molded magnetic material that encloses a portion of the first patterned conductive feature. The adhesive layer extends on a side of the first substrate. The second substrate includes a second patterned conductive feature with multiple turns that form a second winding, and a second molded magnetic material that encloses a portion of the second patterned conductive feature, the second substrate extending on the adhesive layer to magnetically couple the first and second windings.

In a further aspect, a method includes forming a first substrate includes a first patterned conductive feature with multiple turns that form a first winding, and a first molded magnetic material that encloses a portion of the first patterned conductive feature, forming a second substrate includes a second patterned conductive feature with multiple turns that form a second winding, and a second molded magnetic material that encloses a portion of the second patterned conductive feature, attaching a first side of the first substrate to a die attach pad using a first adhesive layer, attaching a first side of the second substrate to a second side of the first substrate using a second adhesive layer, and enclosing the first and second substrates and the first and second adhesive layers in a non-magnetic molded package structure.

### BRIEF DESCRIPTION OF THE DRAWINGS

FIG. 1 is a top perspective view of an integrated circuit packaged electronic device with a low-profile stacked integrated transformer structure having transformer substrates with magnetic mold compound.

FIG. 1A is a partial top plan view of the electronic device of FIG. 1.

FIG. 1B is a partial sectional side elevation view of the electronic device of FIGS. 1 and 1A.

FIG. 2 is a flow diagram of a method of making an electronic device.

FIGS. 3-17 are partial sectional side elevation views illustrating fabrication of a multilayer substrate using magnetic molding compound to form a transformer substrate used in the method of FIG. 2 to fabricate the electronic device of FIG. 1.

FIG. 18 is a top plan view of a panel array structure with rows and columns of transformer substrates fabricated according to the method of FIG. 2 for a transformer primary circuit of the electronic device of FIG. 1.

FIG. 19 is a top plan view of a singulated or separated transformer substrate for a transformer primary circuit of the electronic device of FIG. 1.

FIG. 20 is a top plan view of another panel array structure with rows and columns of transformer substrates fabricated according to the method of FIG. 2 for a transformer secondary circuit of the electronic device of FIG. 1.

FIG. 21 is a top plan view of a singulated or separated transformer substrate for a transformer secondary circuit of the electronic device of FIG. 1.

FIG. 22 is a partial top plan view of a die attach process using a starting lead frame array panel with rows and columns of unit regions during fabrication of the electronic device of FIG. 1 according to the method of FIG. 2.

FIG. 23 is a partial top plan view of an adhesive curing process during fabrication of the electronic device of FIG. 1 according to the method of FIG. 2.

FIG. 24 is a partial top plan view of a first transformer substrate attach process during fabrication of the electronic device of FIG. 1 according to the method of FIG. 2.

FIG. 24A is a partial sectional side elevation view showing the first transformer substrate attached to a die attach pad using a first non-conductive adhesive layer during the first transformer substrate attach process of FIG. 24.

FIG. 25 is a partial top plan view of an adhesive curing process to cure a non-conductive adhesive that attaches the first transformer substrate to a die attach pad during fabrication of the electronic device of FIG. 1 according to the method of FIG. 2.

FIG. 26 is a partial top plan view of a second transformer substrate attach process during fabrication of the electronic device of FIG. 1 according to the method of FIG. 2.

FIG. 26A is a partial sectional side elevation view showing the second transformer substrate attached to the first transformer substrate using a second non-conductive adhesive layer during the second transformer substrate attach process of FIG. 26.

FIG. 27 is a partial top plan view of an adhesive curing process to cure a second non-conductive adhesive that attaches the second transformer substrate to the first transformer substrate during fabrication of the electronic device of FIG. 1 according to the method of FIG. 2.

FIG. 28 is a partial sectional side elevation view showing a plasma clean process following the second transformer substrate attach process according to the method of FIG. 2.

FIG. 29 is a partial top plan view of a wire bonding process according to the method of FIG. 2.

FIG. 30 is a partial top plan view of a molding process according to the method of FIG. 2.

FIG. 31 is a partial top plan view of a lead trim and form process according to the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating.

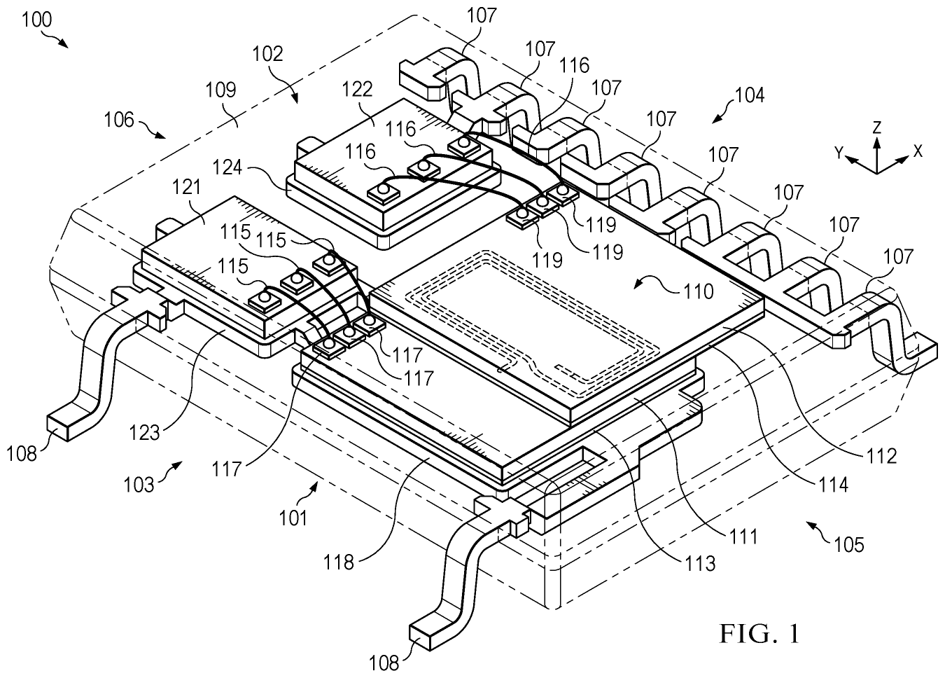

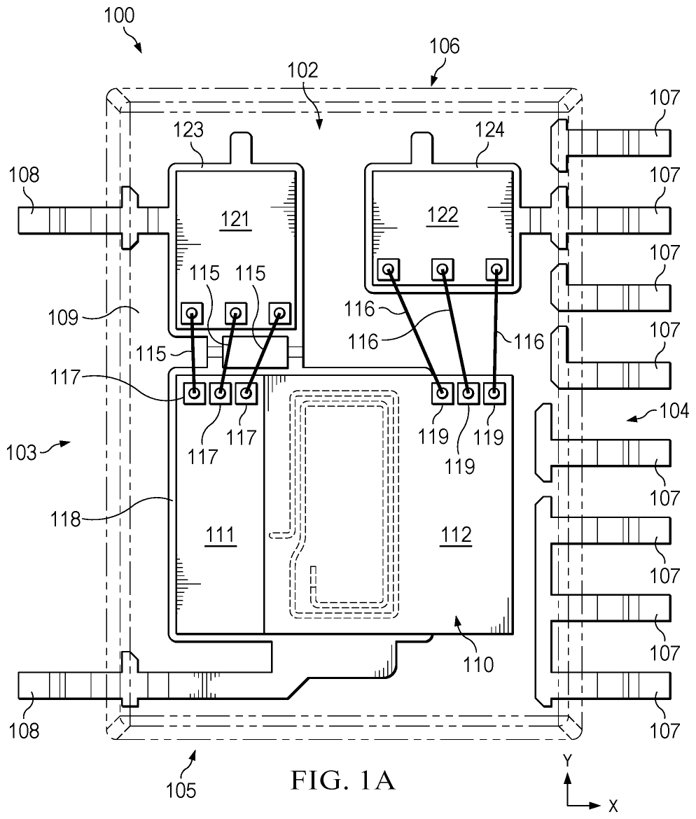

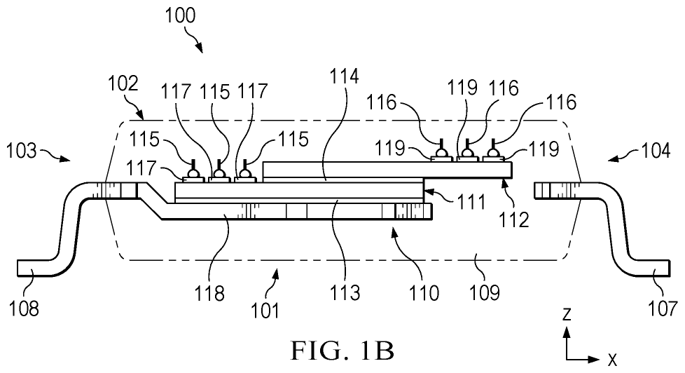

Referring initially to FIGS. 1-1B, FIG. 1 shows a packaged electronic device 100 (e.g., an integrated circuit or IC) with a low-profile stacked integrated transformer 110 having respective first and second transformer substrates 111 and 112 with magnetic mold compound. FIG. 1A shows a partial top view of the electronic device 100, and FIG. 1B shows a partial side view of the integrated transformer 110 in the electronic device 100. The electronic device 100 has a bottom or first side 101 and an opposite top or second side 102, as well as opposite lateral third and fourth sides 103 and 104, respectively, and opposite fifth and sixth ends or sides 105 and 106.

The electronic device 100 is illustrated in an example three-dimensional space with a first direction X, an orthogonal (e.g., perpendicular) second direction Y, and a third direction Z that is orthogonal (e.g., perpendicular) to the respective first and second directions X and Y. The electronic device 100 has leads 107 associated with a secondary-side circuit that extend outward and downward from the fourth side 104, as well as leads 108 associated with a primary-side circuit that extend outward and downward from the third side 103 as shown in FIG. 1. The illustrated leads 107 and 108 are gullwing leads. In other implementations, different numbers of leads and/or different lead shapes can be used, for example “J” leads or leads of a no-lead (e.g., QFN) package (not shown). In addition, these or other implementations can include leads on one or both of the other lateral sides 105 and/or 106 (not shown). The leads 107 and 108 in one example are a conductive metal, such as aluminum or copper or alloys thereof.

The electronic device 100 has a non-magnetic plastic molded package structure 109 that encloses the respective first and transformer second substrates 111 and 112. As shown in FIGS. 1 and 1A, electrical connections in the primary and secondary-side circuits of the electronic device 100 includes bond wires 115 and 116 as well as other bond wires (not shown), which are enclosed by the package structure 109. As shown in FIGS. 1 and 1B, the first and second transformer substrates 111 and 112 are formed in a stacked arrangement along the third direction Z, with a first non-conductive adhesive layer 113 that adheres a lower or first side of the first transformer substrate 111 to a conductive metal die attach pad 118, and a second non-conductive adhesive layer 114 that adheres a lower or first side of the second transformer substrate 112 to a second or top side of the first transformer substrate 111.

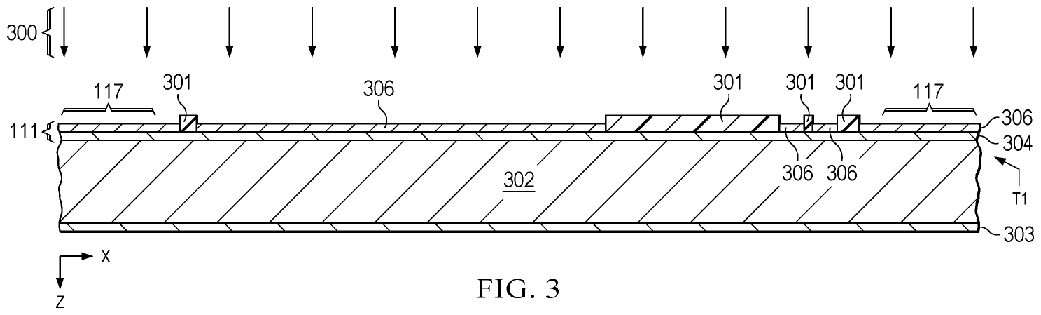

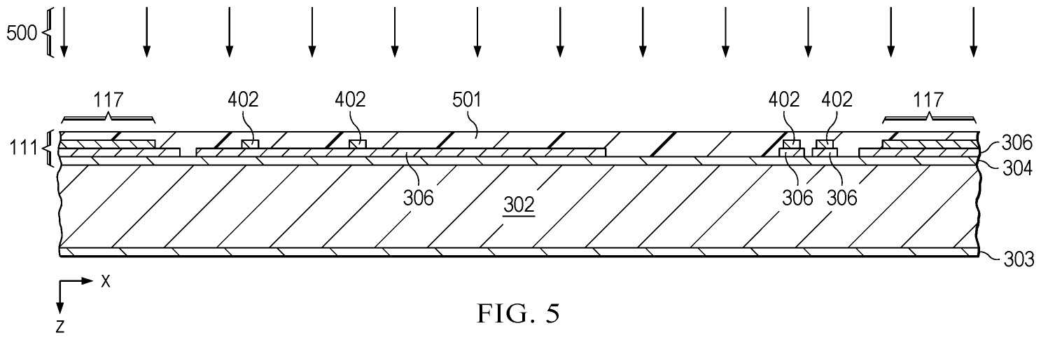

As discussed further below in connection with FIGS. 3-17, the first transformer substrate 111 includes a first patterned conductive feature (e.g., 306 in FIGS. 3-17) with multiple turns that form a first winding to provide a primary winding for the transformer 110. The first transformer substrate 111 also includes a first molded magnetic material (e.g., 501 in FIGS. 5-17) that encloses a portion of the first patterned conductive feature, with the first adhesive layer 113 extending between the first side of the first substrate 111 and the die attach pad 118. The first substrate 111 also includes conductive terminals 117 as shown in FIGS. 1 and 1A.

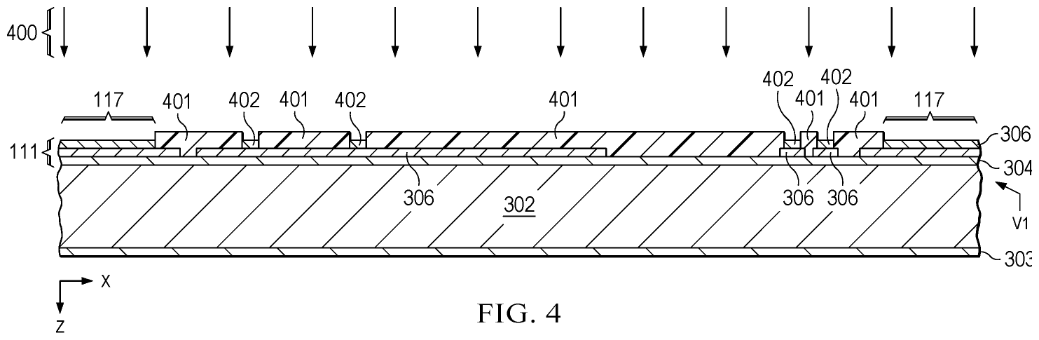

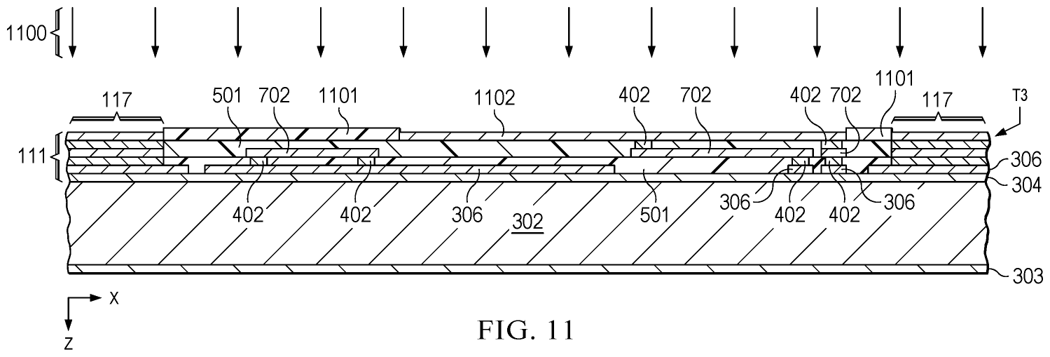

The second transformer substrate 112 includes a second patterned conductive feature with multiple turns that form a second winding, for example, to provide a secondary winding for the transformer 110. In addition, the second transformer substrate 112 includes a second molded magnetic material that encloses a portion of the second patterned conductive feature, and the second substrate 112 extends on the second adhesive layer 114 to magnetically couple the first and second windings. The second substrate 112 also includes conductive terminals 119 as shown in FIGS. 1 and 1A. In one example, the first and second substrates 111, 112 each include multiple levels of patterned conductive features (e.g., 306, 702, 1102 in FIGS. 11-17 below), as well as conductive vias (e.g., 402 in FIGS. 4-17).

As shown in FIGS. 1 and 1A, the example electronic device 100 also includes one or more semiconductor dies. A first semiconductor die 121 is attached to a first die attach pad 123, and conductive features (e.g., bond pads) of the first semiconductor die 121 are coupled to the conductive terminals 117 of the first substrate 111 by the illustrated bond wires 115, for example, for interconnections in the primary-side circuitry of the electronic device 100. A second semiconductor die 122 is mounted on a second die attach pad 124. Conductive features (e.g., bond pads) of the second semiconductor die 122 are coupled to the conductive terminals 119 of the second substrate 112 by the bond wires 116, for example, for interconnections in the secondary-side circuitry of the electronic device 100. The semiconductor dies 121 and 122, as well as the transformer 110, the die attach pads 118, 123, and 124, and the bond wires 115 and 116 are enclosed in this example by the package structure 109.

The first semiconductor die 121 has a first circuit, such as switching circuitry of the primary-side circuit, and the second semiconductor die 122 has a second circuit, such as switching circuitry of the secondary-side circuit of the electronic device 100. The first circuit of the first semiconductor die 121 is coupled to the first substrate 111 by the bond wires 115 and the conductive terminals 117, and the second circuit of the second semiconductor die 122 is coupled to the second substrate 112 by the bond wires 116 and the conductive terminals 119. The electronic device 100 can include further electrical connections (e.g., further bond wires, not shown) that electrically connect further conductive features of one or both of the semiconductor dies 121, 122 and/or further conductive terminals of one or both of the substrates 111, 112 to respective ones of the conductive leads 107, 108. For example, the first substrate 111 and/or the first circuit of the first semiconductor die 121 can be electrically connected to one or more of the primary-side conductive leads 108, and the second substrate 112 and/or the second circuit of the second semiconductor die 122 can be electrically connected to one or more of the secondary-side conductive leads 107 of the electronic device 100.

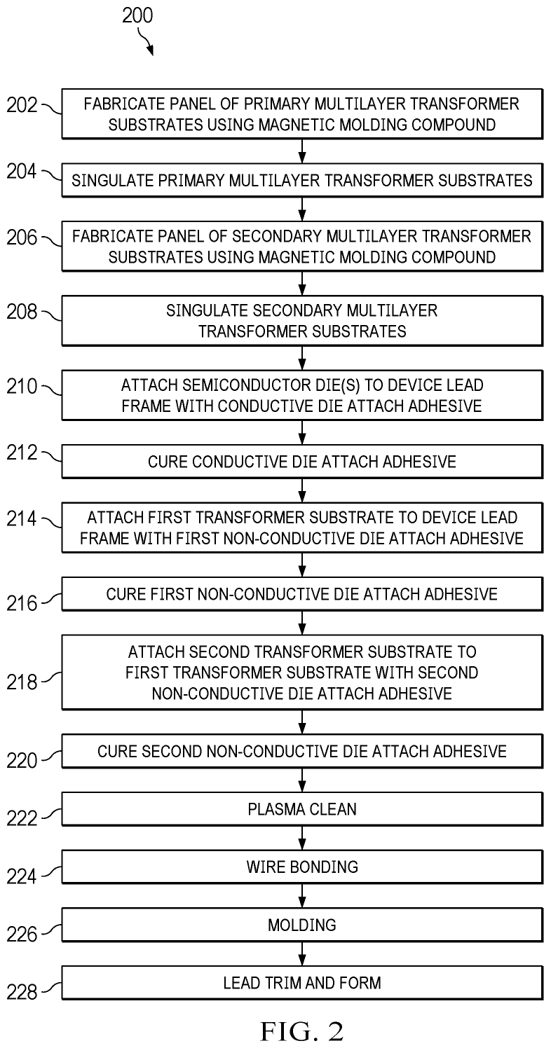

FIG. 2 shows a method 200 of making an electronic device, and FIGS. 3-31 show fabrication processing to make the electronic device 100 of FIGS. 1-1B according to the method 200. The method 200 includes fabricating a panel of primary multilayer transformer substrates using magnetic molding compound at 202. FIGS. 3-17 show fabrication of a multilayer transformer substrate using magnetic molding compound to form the first transformer substrate 111 used in the method of FIG. 2 to fabricate the electronic device 100, and similar processing is used in one implementation to fabricate the second transformer substrate 112 of the electronic device 100. In other implementations, one or both of the first and second substrates 111, 112 can be single level substrate structures, for example, having conductive features that form a respective coil winding as well as magnetic molded material.

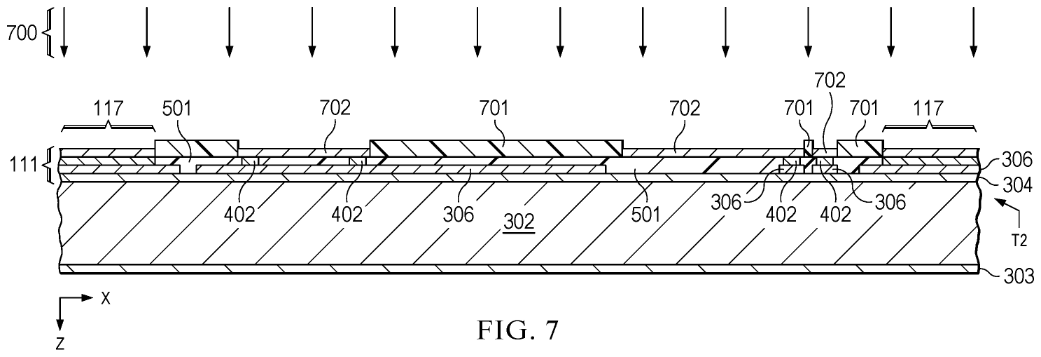

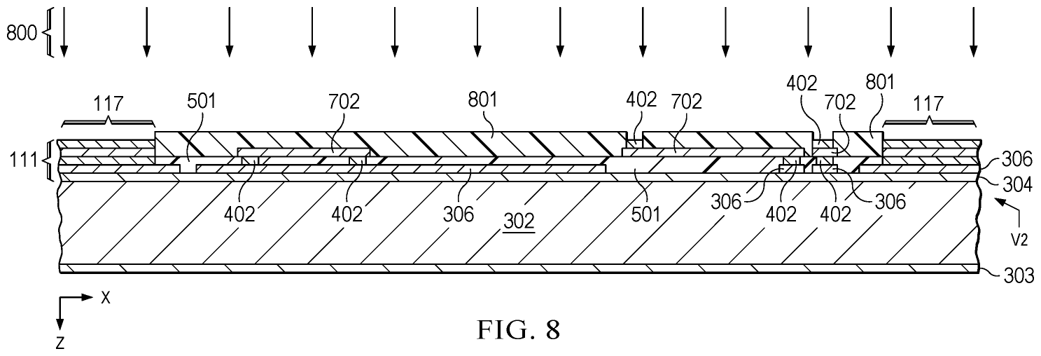

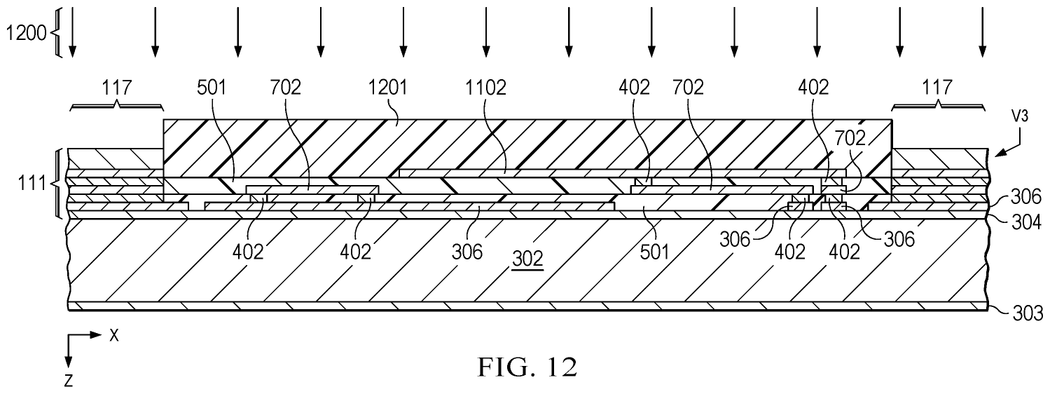

In the illustrated multilevel examples, the multilevel transformer substrate fabrication at 202 includes forming a first level (e.g., T1, V1 in FIGS. 3 and 4 below) on a carrier structure 302 in FIGS. 3 and 4, and subsequently forming a second level (e.g., T2, V2 in FIGS. 7 and 8) on the first level, as well as forming a third level (e.g., T3, V3 in FIGS. 11 and 12) on the second level, after which the carrier structure is removed from the first level. Following the fabrication of multiple rows and columns of the transformer substrate panel array, individual transformer substrates are separated from the panel structure and used as components in the fabrication of a panel or array of the electronic devices 100.

FIGS. 3-6 show formation of the first level of the multilevel first transformer substrate 111 in one example, using an electroplating process 300 and a patterned plating mask 301. The illustrated example forms the first level having the first molded magnetic features, the first patterned conductive feature 306 with multiple turns that form the first winding, and initial portions of the conductive terminals 117 of the first transformer substrate 111. The first level formation starts with forming the first trace layer T1 using a stainless-steel carrier 302, such as a panel or strip with multiple prospective transformer substrate sections, one of which is shown in FIG. 3. The carrier structure 302 includes thin copper seed layers 303 and 304 formed by a blanket deposition process (not shown) on the respective bottom and top sides of the carrier structure 302 to facilitate electroplating via the process 300. The electroplating process 300 deposits copper onto the upper copper seed layer 304 in the portions of the topside of the carrier structure that are exposed through the patterned plating mask 301 to form the first patterned conductive features 306 that form a primary transformer winding for the transformer 110 in the electronic device 100 of FIG. 1.

FIG. 4 shows the multilevel first transformer substrate 111 after the process 300 is completed and the plating mask 301 has been removed to form the first via layer V1 with the first conductive features (e.g., coil) 306. A second electroplating process 400 is performed in FIG. 4 using a patterned second plating mask 401 (e.g., a copper pillar or via plating process). The electroplating process 400 deposits further copper onto exposed portions of the first conductive features 306 to form vias 402 and further portions of the conductive terminals 117 of the first via level V1 in the areas exposed by the second plating mask 401. After the process 400 is completed, the second plating mask 401 is removed.

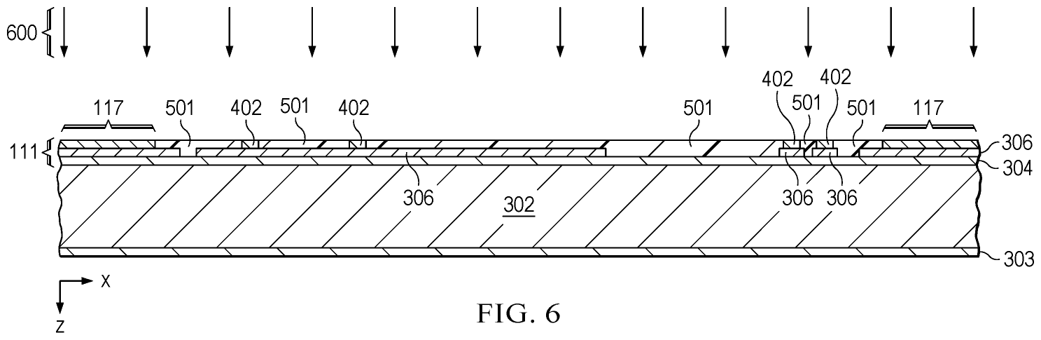

FIGS. 5 and 6 show the formation of the first molded magnetic features in the first level. A compression molding process 500 is performed in FIG. 5 to form molded magnetic features 501 on exposed portions of the conductive features 306 of the first trace layer T1 and the vias (e.g., 402) of the first via layer V1 to an initial thickness that covers the first trace layer T1 and the first via layer V1. A grinding process 600 is performed in FIG. 6, which grinds upper portions of the molded magnetic material 501 and exposes the upper portions of the first trace layer T1 and the first via layer V1. In another example, a chemical etch is used. In a further example, a chemical mechanical polishing process is used. As shown in FIG. 6, the first molded magnetic material 501 encloses a portion of the first patterned conductive features 306.

FIGS. 7-10 show formation of the second level of the multilevel transformer substrate 111, including forming the second trace layer T2, the second via layer V2 and the second portions of the first molded magnetic features 501 of the first substrate 111. In one example, the processing used to form the second level is similar to that used to form the first level, although not a requirement of all possible implementations. In the illustrated example, the second level processing forms the second level T2, V2 on the first level T1, V1, where the second level T2, V2 has second patterned conductive features 702 and second portions of the first molded magnetic features 501. FIG. 7 shows the multilevel transformer substrate 111 undergoing an electroplating process 700 with a patterned plating mask 701. The electroplating process 700 deposits copper onto the top side of the portions of the finished first level that are exposed through the plating mask 701 to form the second trace layer T2 including patterned conductive features 702 and further portions of the conductive terminals 117. After the process 700 is completed, the plating mask 701 is removed.

FIG. 8 shows the multilevel transformer substrate 111 undergoing another electroplating process 800 using another plating mask 801 (e.g., a copper pillar plating process). The electroplating process 800 deposits further copper to form the vias 402 and further portions of the conductive terminals 117 of the second via level V2 in the areas exposed by the plating mask 801. After the process 800 is completed, the plating mask 801 is removed.

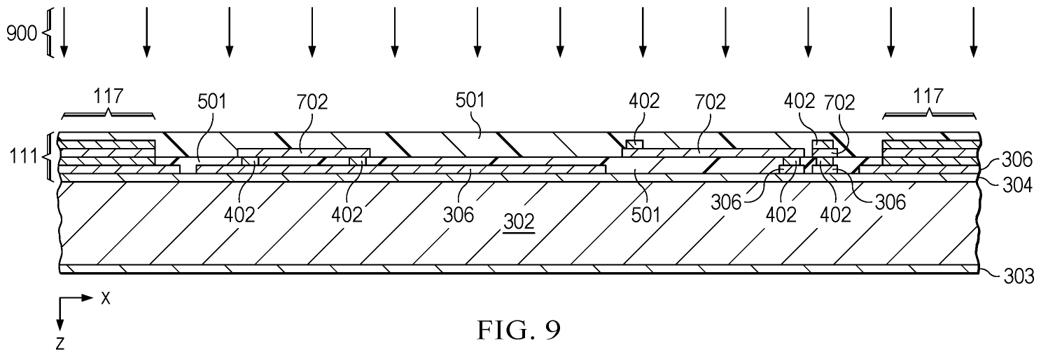

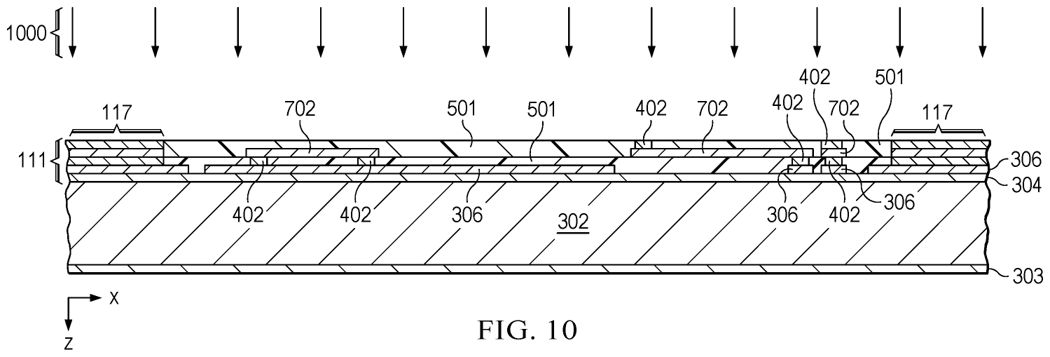

FIGS. 9 and 10 show formation of the second portions of the molded magnetic features 501 in the second level using compression molding and grinding. A compression molding process 900 is performed in FIG. 9, which forms molded magnetic features 501 on exposed portions of the conductive features (e.g., coil return sections 702 ) of the second trace layer T2 and the vias (e.g., 402) of the second via layer V2 to an initial thickness that covers the second trace layer T2 and the second via layer V2. A grinding process 1000 is performed in FIG. 10, which grinds upper portions of the second portions of the molded magnetic material 501 and exposes the upper portions of the second trace layer T2 and the second via layer V2. In another example, a chemical etch is used. In a further example, a chemical mechanical polishing process is used.

FIGS. 11-14 show formation of a third level of the multilevel first transformer substrate 111, including forming a third trace layer T3, a third via layer V3, and third portions of the molded magnetic features 501. In one example, the processing used to form the third level is similar to that used to form the first and second levels, although not a requirement of all possible implementations. In the illustrated example, the third level processing forms the third level T3, V3 on the second level T2, V2, where the third level T3, V3 has the third portions of the molded magnetic features 501, a third patterned conductive feature 1102 with multiple turns that form further turns of the transformer winding, and further portions of the conductive terminals 117 of the first substrate 111.

FIG. 11 shows the multilevel first transformer substrate 111 undergoing an electroplating process 1100 with another patterned plating mask 1101. The electroplating process 1100 deposits copper onto the top side of the portions of the finished second level that are exposed through the patterned plating mask 1101 to form the third trace layer T3 including third patterned conductive features 1102 and further portions of the conductive terminals 117. After the process 1100 is completed, the plating mask 1101 is removed.

FIG. 12 shows the multilevel transformer substrate 111 undergoing another electroplating process 1200 using another via plating mask 1201 (e.g., a copper pillar or via plating process). The electroplating process 1200 deposits further copper to form further portions of the conductive terminals 117 of the third via level V3 in the areas exposed by the via plating mask 1201. After the electroplating process 1200, the via plating mask 1201 is removed.

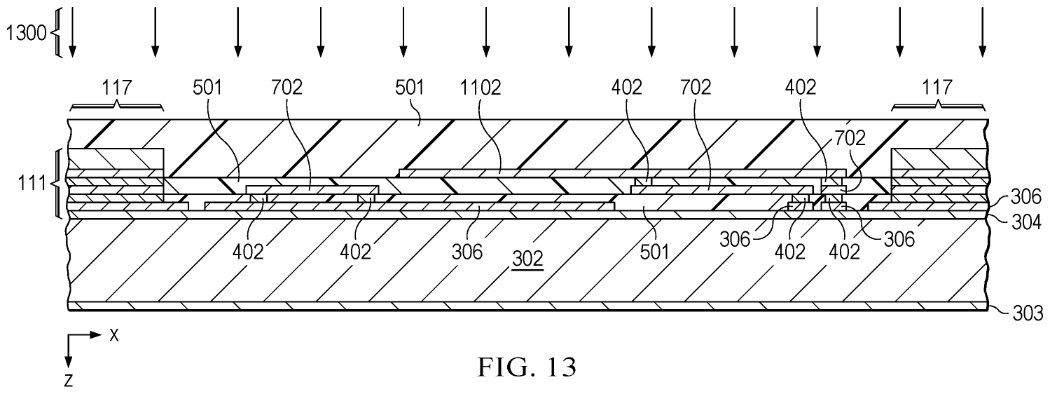

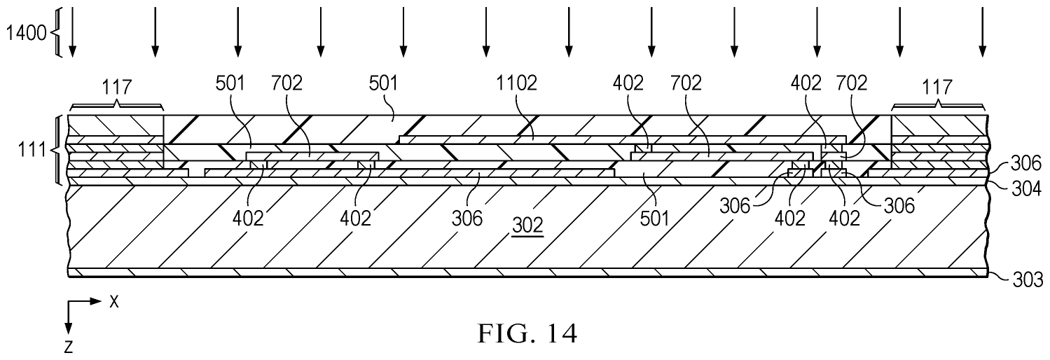

FIGS. 13 and 14 show the formation of the third molded portions of the magnetic features 501 in the third level using compression molding and grinding. A compression molding process 1300 is performed in FIG. 13, which forms further molded magnetic features 501 on exposed portions of the conductive features of the third trace layer T3 of the third via layer V3 to an initial thickness that covers the third trace layer T3 and the third via layer V3. A grinding process 1400 is performed in FIG. 14, which grinds upper portions of the molded magnetic material 501 and exposes the upper portions of the third trace layer T3 and the third via layer V3. In another example, a chemical etch is used. In a further example, a chemical mechanical polishing process is used.

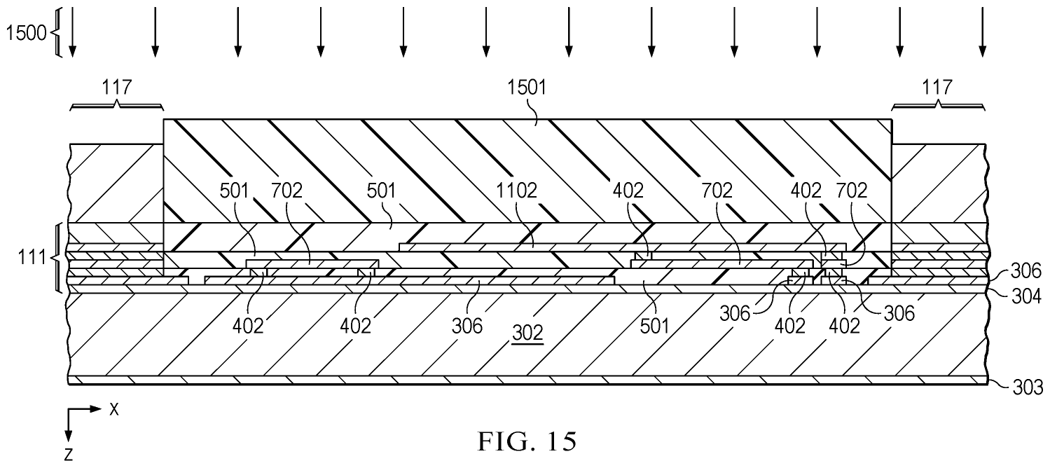

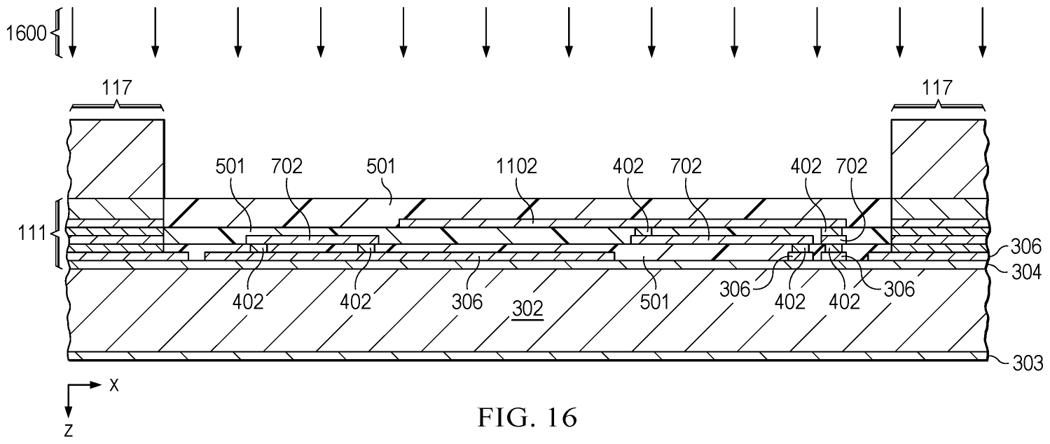

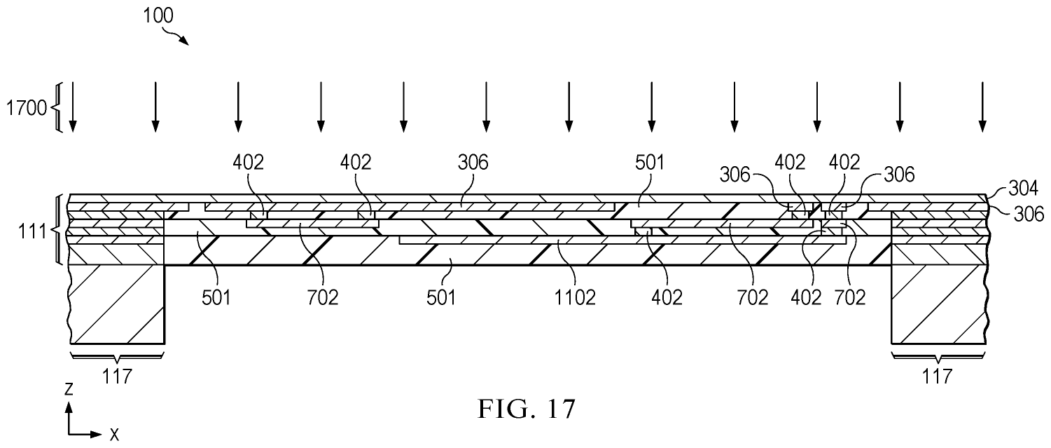

Referring also to FIGS. 15-17, the illustrated first multilevel transformer substrate 111 has integrated terminals 117, which are further extended along the Z direction in FIGS. 15 and 16. In FIG. 15, a further electroplating or other deposition processes 1500 is performed using another plating mask 1501. The process 1500 further extends the Z direction dimension of the conductive terminals 117, and the mask 1501 is removed by a process 1600 in FIG. 16. In FIG. 17, a removal process 1700 is performed that removes the carrier structure 302, 303, 304 from the first level of the multilevel transformer substrate 111.

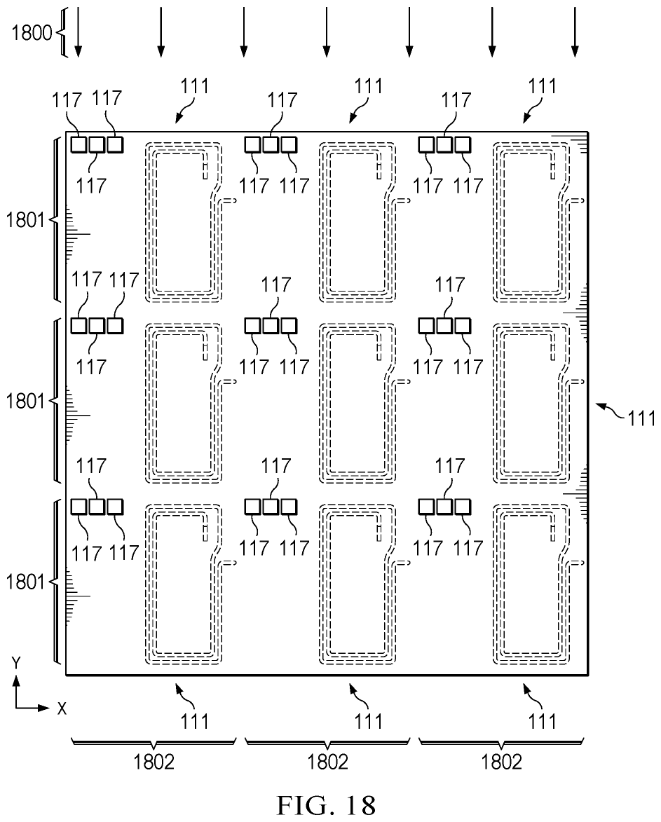

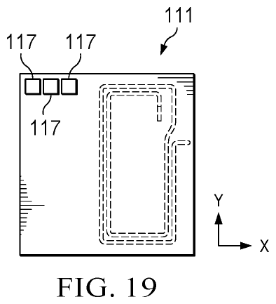

Returning to FIG. 2, the method 200 continues at 204 with singulating or separating the first multilayer transformer substrates 111 from the panel array structure used in the processing at 202. FIG. 18 shows an example panel array structure with rows and columns of the first transformer substrates 111 fabricated at 202 of FIG. 2 for transformer primary circuitry of the electronic device 100. In this example, the panel undergoes a saw cutting or other separation process 1800 that separates individual first substrates 111 from the panel structure. FIG. 19 shows a top view of a singulated or separated transformer substrate 111 for the transformer primary circuit of the electronic device 100 of FIGS. 1-1B above.

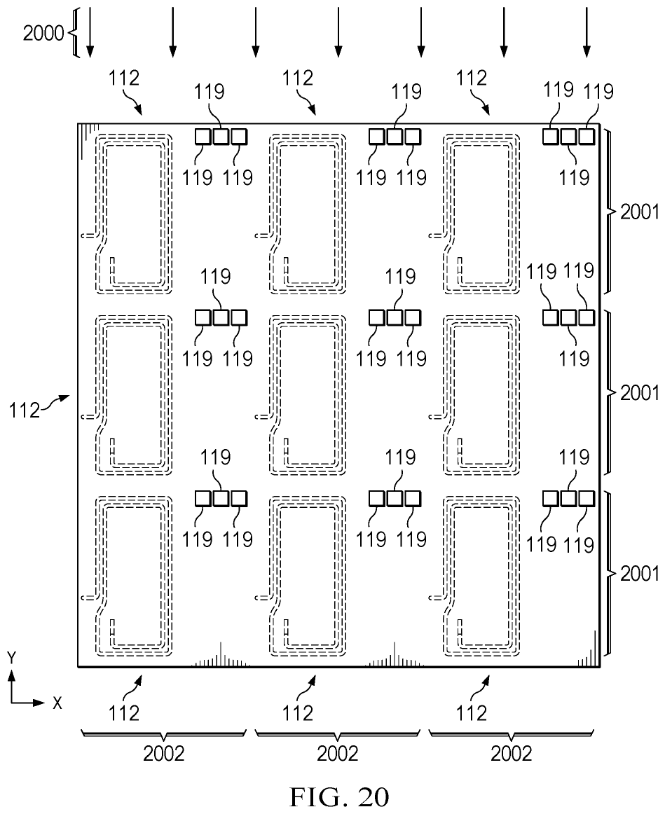

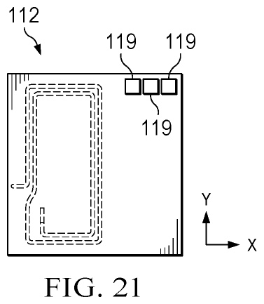

The method 200 in FIG. 2 continues at 206 with fabrication of a panel of the second multilayer transformer substrates 112 using magnetic molding compound. In one example, the panel array of the second transformer substrates 112 is processed at 206 using the systems and techniques described above in connection with FIGS. 3-17, along with corresponding secondary side transformer masks (not shown) to form a multilevel second transformer substrate 112 that includes a second patterned conductive feature with multiple turns that form a second winding, and a second molded magnetic material that encloses a portion of the second patterned conductive feature. Referring also to FIGS. 20 and 21, FIG. 20 shows an example panel array structure with rows and columns of the second transformer substrates 112 fabricated at 206 of FIG. 2 for transformer secondary circuitry of the electronic device 100. In this example, the panel undergoes a saw cutting or other separation process 2000 that separates individual second substrates 112 from the panel structure at 208 in FIG. 2. FIG. 21 shows a top view of a singulated or separated second transformer substrate 112 for the transformer secondary circuit of the electronic device 100.

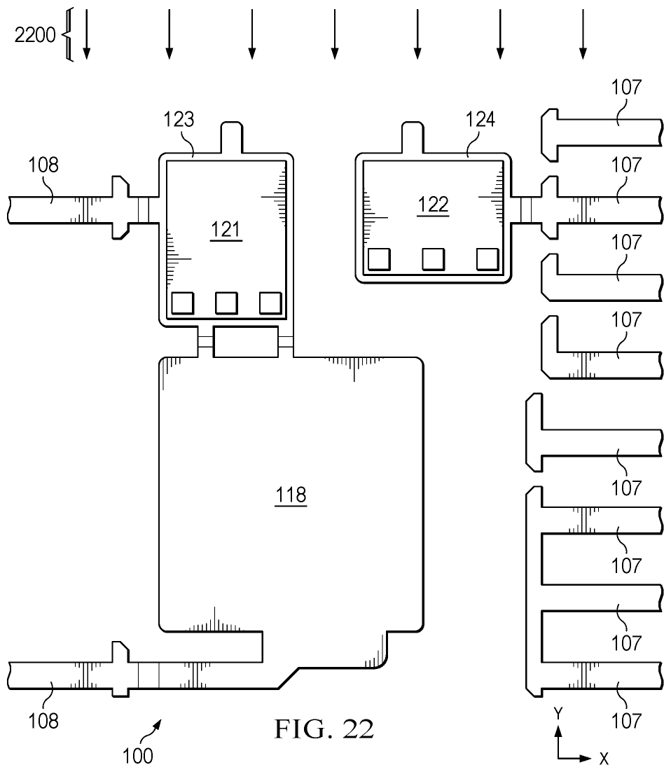

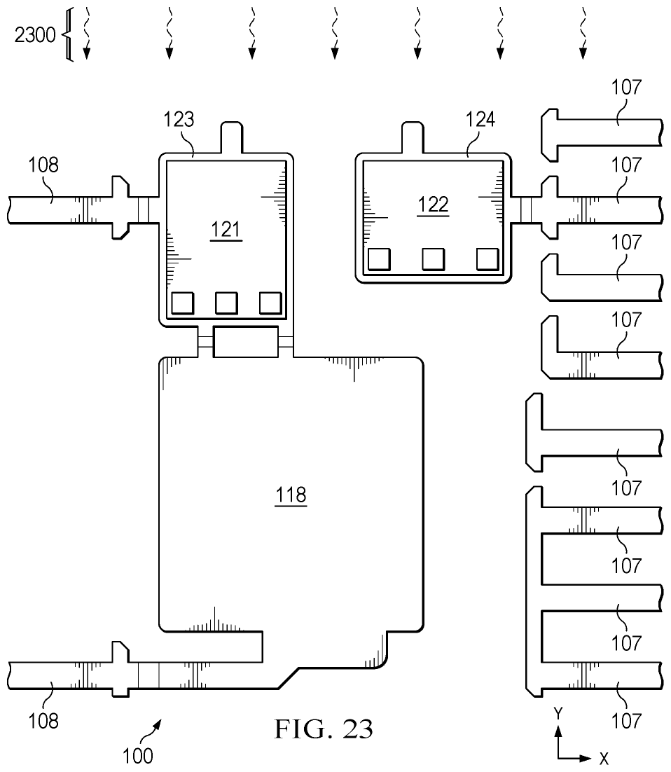

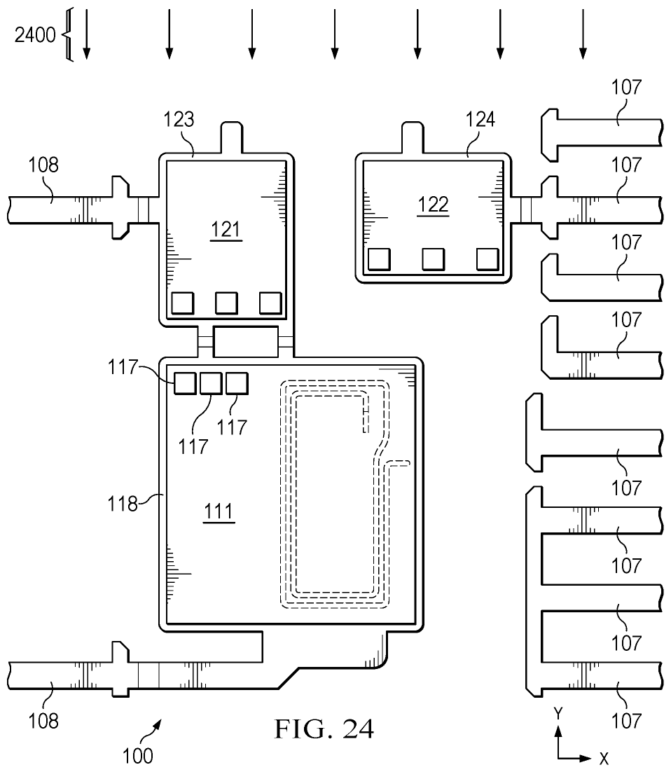

The method 200 continues at 210 in FIG. 2 with semiconductor die attachment processing. The illustrated example includes processing of multiple prospective electronic devices 100 in an array of rows and columns of unit or device areas, starting with a lead frame panel array structure. FIG. 22 shows one example, in which a die attach process 2200 is performed that attaches the first and second semiconductor dies 121 and 122 to the respective die attach pads 123 and 124 in each unit area of the lead frame panel array. In one example, the semiconductor dies 121 and 122 are attached to the respective die attach pads 123 and 124 using a conductive die attach adhesive (not shown). At 212 in FIG. 2, the method 200 continues with thermal processing to cure the conductive die attach adhesive used in the attach processing at 210. FIG. 23 shows one example, in which an adhesive curing process 2300 is performed that cures the die attach adhesive used in attaching the semiconductor dies 121 and 122.

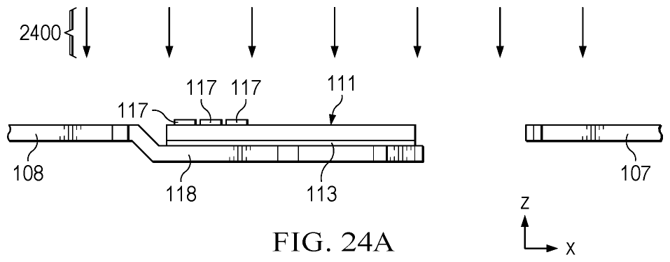

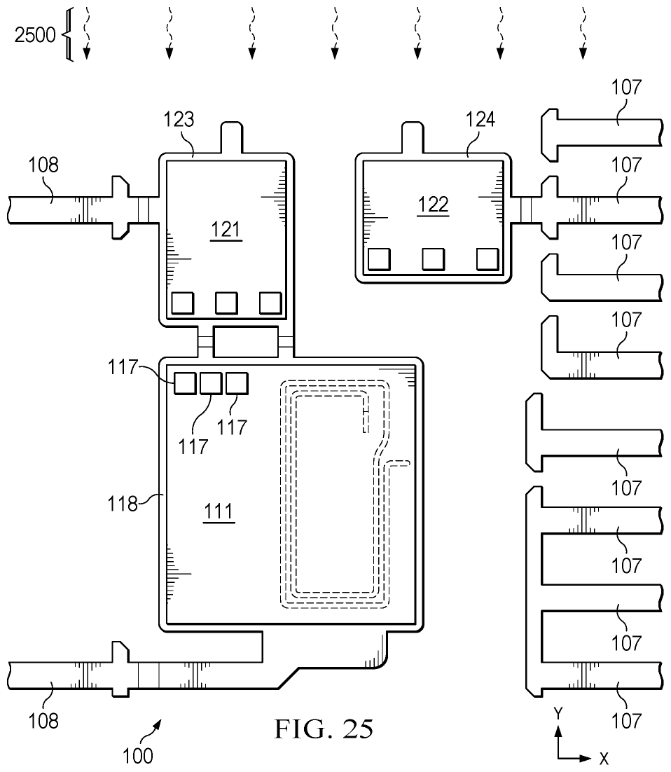

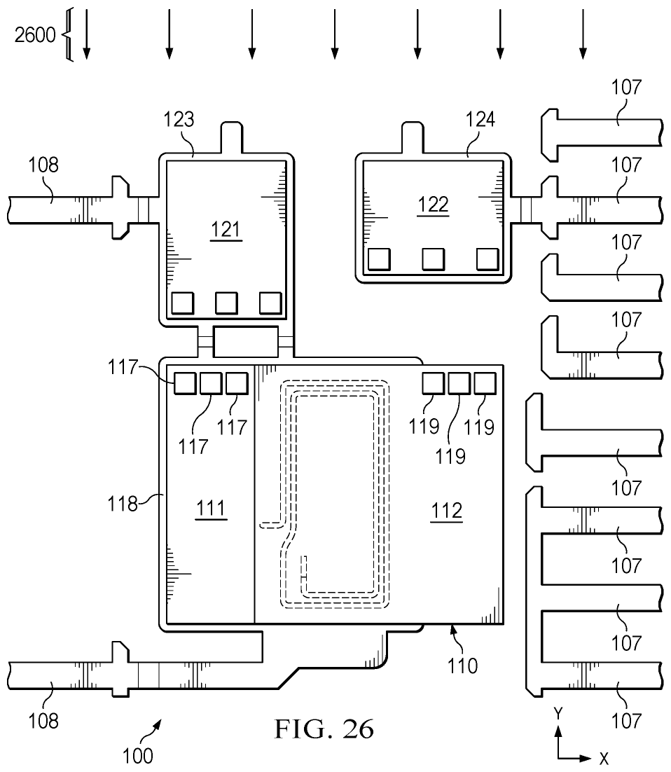

The method 200 continues at 214 in FIG. 2 with attaching a first transformer substrate 111 to the die attach pad 118 of the starting lead frame in each unit area of the lead frame panel array. FIGS. 24 and 24A show one example, in which an attach process 2400 is performed, for example, using automated pick and place equipment (not shown). The attach process 2400 attaches a separated or singulated first transformer substrate 111 to the respective die attach pad 118 of each unit area using a non-conductive first adhesive layer 113. In one example, the adhesive layer 113 is selectively deposited or otherwise formed on select portions of the top sides of the die attach pads 118 in each unit area of the lead frame panel array and pick and place equipment (not shown) positions the first transformer substrate 111 with a lower or first side thereof on and in contact with at least a portion of the first adhesive layer 113 as shown in FIG. 24A. At 216 in FIG. 2, the method 200 continues with thermal processing to cure the non-conductive first adhesive layer 113 used in the attach processing at 214. FIG. 25 shows one example, in which an adhesive curing process 2500 is performed that cures the adhesive layer 113 used in attaching the first transformer substrate 111 to the die attach pad 118.

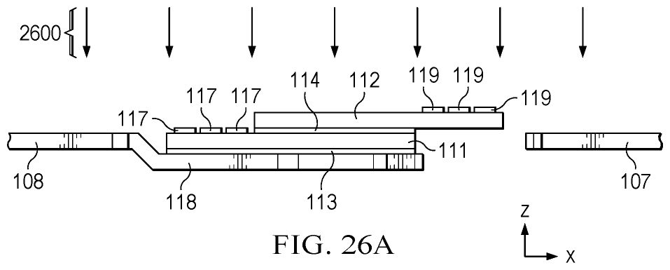

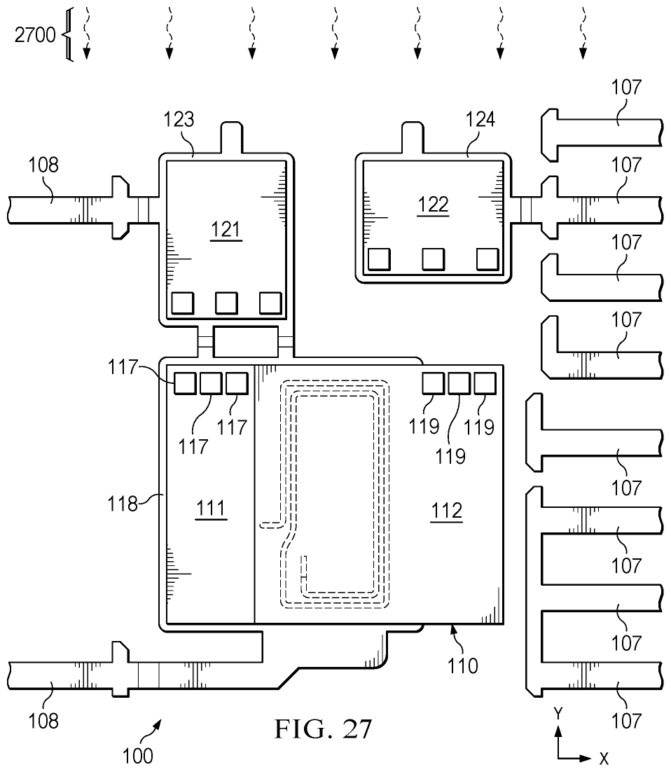

The method 200 continues at 218 and 220 in FIG. 2 in order to attach the lower or first side of the second transformer substrate 112 to the upper or second side of the first transformer substrate 111 using non-conductive adhesive at 218. FIGS. 26 and 26A show one example, in which an attach process 2600 is performed, for example, using automated pick and place equipment (not shown). The attach process 2600 attaches a separated or singulated second transformer substrate 112 to the previously attached first transformer substrate 111 of each unit area using a non-conductive second adhesive layer 114. In one example, the adhesive layer 114 is selectively deposited or otherwise formed on select portions of the top sides of the first transformer substrates 111 in each unit area of the lead frame panel array and pick and place equipment (not shown) positions the second transformer substrate 112 with the first side thereof on the second adhesive layer 114 above top or second side of the first transformer substrate 111 as shown in FIG. 26A. At 220 in FIG. 2, the method 200 continues with thermal processing to cure the non-conductive second adhesive layer 114 used in the attach processing at 218. FIG. 27 shows one example, in which an adhesive curing process 2700 is performed that cures the second adhesive layer 114 used in attaching the second transformer substrate 112 to the first transformer substrate 111.

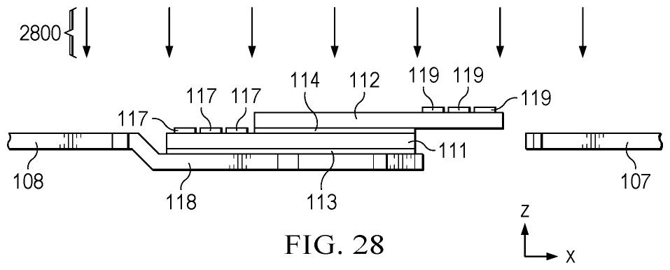

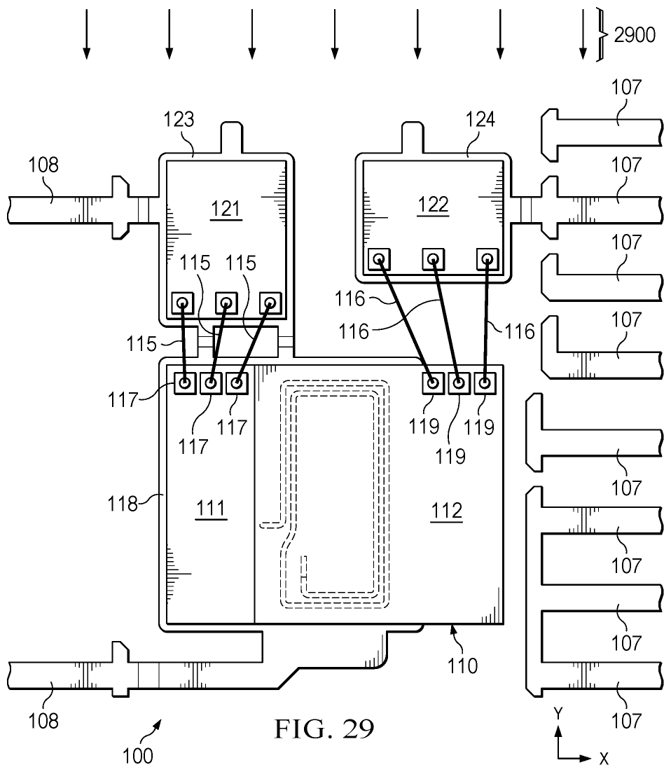

The method 200 in one example also includes a plasma clean operation at 222 in FIG. 2. FIG. 28 shows one example, in which a plasma clean process 2800 is performed that cleans the structure in each unit area of the lead frame panel array. The method 200 of FIG. 2 continues at 224 with electrical connection processing, in this case, wire bonding. FIG. 29 shows one example, in which a wire bonding process 2900 is performed that forms the bond wires 115 and 116 to provide electrical connections in the primary and secondary-side circuitry of the individual electronic devices in each unit area of the lead frame panel array.

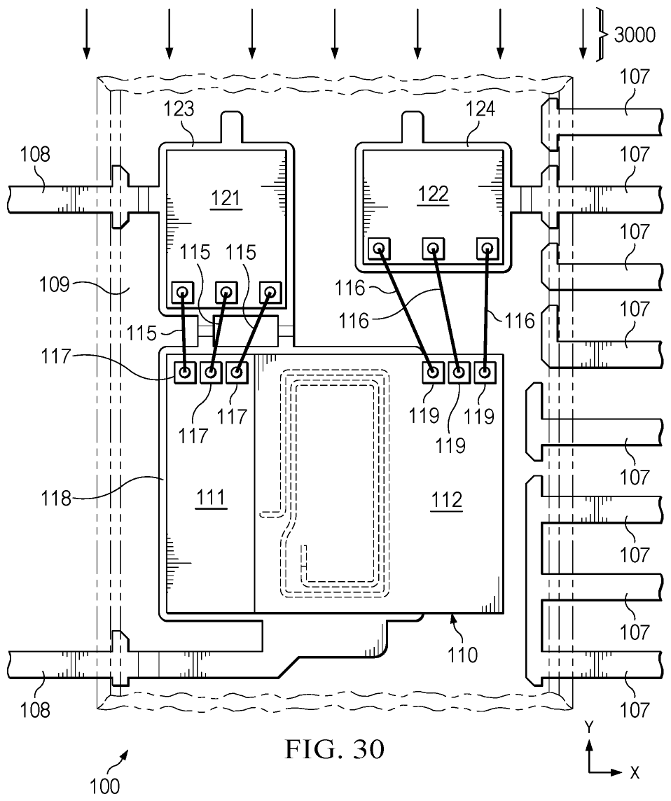

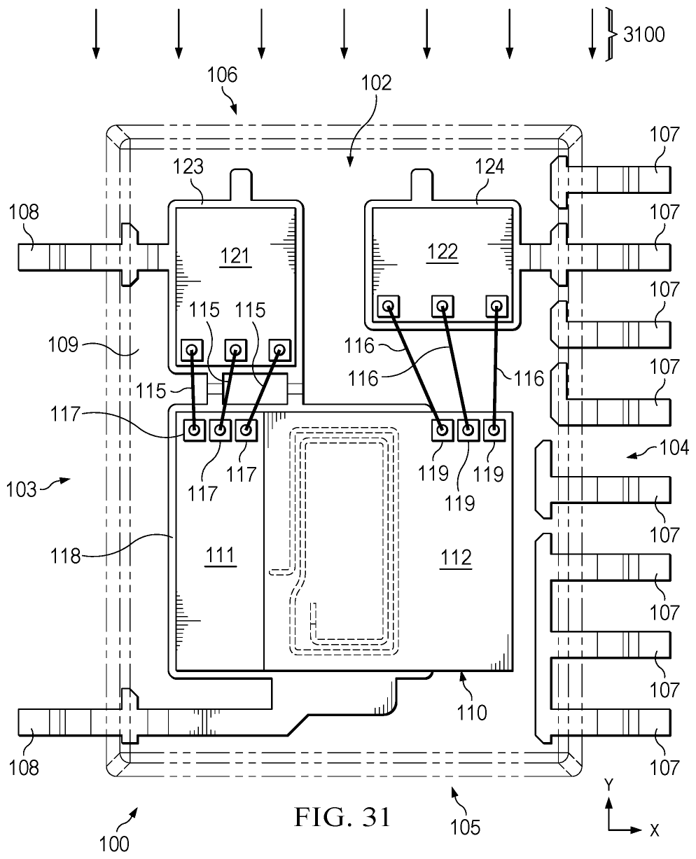

The method 200 also includes molding at 226 in FIG. 2. FIG. 30 shows one example, in which a molding process 3000 is performed that creates molded package structures 109, for example, along columns of the lead frame panel array (Not Shown). The method 200 in this example also includes lead trimming and forming, as well as package separation processing at 228 in FIG. 2. FIG. 31 shows one example, in which final processing 3100 is performed that separates individual packaged electronic devices 100 from the starting lead frame panel array, and trims and forms the leads (e.g., gullwing leads 107 and 108 as shown in FIG. 1.

The example method can be used in the fabrication of packaged electronic devices (e.g., ICs), such as the electronic device 100 described above. Moreover, portions of the method 200 can be used to fabricate transformers by stacking the above described first and second transformer substrates 111 and 112 using the adhesive layer 114. Illustrated examples provide transformer substrate stacking using die attach processing systems and equipment and curing of associated non-conductive adhesive layers 113 and 114, as well as construction of the transformer substrates 111 and 112 using magnetic mold compound in a molded routable lead frame structure. In one implementation, the transformer substrate processing at 202 and 206 in FIG. 2 uses compression molding with magnetic mold compound formed in a strip structure (not shown). Table 1 below shows suitable example magnetic mold compound components and properties that can be used in certain implementations, and other suitable magnetic mold compounds can be used in other implementations of the method 200, for example, by compression molding as described above.

| | | | MMC Supplier | | | |
|---|---|---|---|---|---|---|
| | | | Panasonic | [symbol] | [symbol] | N [symbol] Go [symbol] i |
| | | | Feature | | | |
| | | | Same as previous one | [symbol] | [symbol] | [symbol] |
| Item | | Unit | X [symbol] (Current) | [symbol] (New) | [symbol] (New) | [symbol] (New) |
| Flowability | Spiral flow | cm | 72 | 67 | 165 | 137 |
| | Melt viscosity | Pa · s | 8 | 33 | — | — |
| | Gel time | sec | 44 | 52 | 69 | 70 |
| Mechanical char. | CTE1/CTE2 | ppm/C. | 15/34 | 14/25 | 16/37 | 18/42 |
| | [symbol] g | | 141 | 223 | 172 | 185 |
| | Flexural strength(25 C.) | MPa | 165 | 115 | 149 | 125 |
| | Flexural modulus(25 C.) | GPa | 40 | 31 | 28 | 28 |
| | Flexural strength(250 C.) | MPa | 21 | 11 | 20 | 10 |
| | Flexural modulus(250 C.) | GPa | 1.6 | 0.8 | 1.3 | 0.9 |
| Electrical char. | Breakdown voltage(25 C) | V/mm | −300 | −620 | −570 | −420 |
| | Breakdown voltage(110 C) | V/mm | −250 | −750 | −275 | −160 |
| Magnetic char. | Permeability (toroidal) | — | 28 | 26 | 24 | 26 |

[symbol]

indicates data missing or illegible when filed

The described examples and variations thereof facilitate improved integrated magnetic circuit performance as well as reduced or controlled device height and mitigation of air bubbles another packaging problems associated with other forms of integrated magnetic circuitry. Moreover, the described solutions provide cost advantages compared with other approaches discussed above. In the illustrated example, the stacked first and second transformer substrates 111 and 112 provide an integrated transformer structure with low profile, and without requiring additional or external magnetic sheets, which facilitates improved transformer operating parameters and reduces fabrication cost. In addition, the use of the magnetic molded substrates 111 and 112 facilitates improved transformer winding design possibilities, including the ability to provide more turns on one or both of the primary and/or secondary sides compared with conventional laminate substrate winding approaches. In addition, the magnetic molding compound and the substrate construction increases the transformer efficiency due to little or no gap between the windings and the magnetic core formed by the compression molded magnetic molding material 501. Furthermore, the use of non-conductive adhesive layers (e.g., 113 and 114 above) facilitates improved isolation capability in the design of packaged electronic devices, such as high voltage switching circuitry of an isolated power supply. In addition, the low profile stacking process used in fabrication of the integrated transformer 110 can be used in combination with an underfill epoxy to ensure a desired level of isolation performance and reliability of a closed loop isolated transformer. Furthermore, the described examples provide tightly integrated magnetic circuitry with close coupling of the transformer windings and the magnetic core structure formed by the molded magnetic material, which facilitates reduced partial discharge yield loss and the lamination yield loss associated with laminate or other transformer solutions. In addition, the described examples provide cost reduction advantages compared with other solutions, where the described structure and fabrication techniques do not require individual magnetic pieces, and integration in the packaged electronic device 100 is achieved with a simplified assembly process to reduce cost. In other implementations, more complex transformer structures can be designed based on the described fabrication process 200. The use of the magnetic molding material (e.g., 501 above) allows construction of the transformer substrates 111 and 112 in processes that use other (e.g., dielectric) mold compound, while providing good magnetic properties. The ease of integration facilitates efficient assembly processing and simplifies the assembly process due to fewer components needed to be integrated into the packaged electronic device 100. Furthermore, the low profile of the integrated transformer 110 mitigates or avoids air bubbles or other voids in the structure and provides significant molding and packaging advantages compared with laminate transformer structures, which further benefits the isolation capabilities of the transformer 110.

Modifications are possible in the described examples, and other implementations are possible, within the scope of the claims.

What is claimed is:

1. An electronic device, comprising:
a first substrate including a first patterned conductive feature with multiple turns that form a first winding, and a first molded magnetic material that encloses a portion of the first patterned conductive feature;
an adhesive layer on a side of the first substrate;
a second substrate including a second patterned conductive feature with multiple turns that form a second winding, and a second molded magnetic material that encloses a portion of the second patterned conductive feature, the second substrate extending on the adhesive layer to magnetically couple the first and second windings; and
a package structure that encloses the first and second substrates.

2. The electronic device of claim 1, comprising another adhesive layer between another side of the first substrate and a die attach pad.

3. The electronic device of claim 2, further comprising:
a first semiconductor die enclosed by the package structure and having a first circuit electrically coupled to the first substrate; and
a second semiconductor die enclosed by the package structure and having a second circuit electrically coupled to the second substrate.

4. The electronic device of claim 3, wherein the first and second substrates each include multiple levels of patterned conductive features and conductive vias.

5. The electronic device of claim 2, wherein the first and second substrates each include multiple levels of patterned conductive features and conductive vias.

6. The electronic device of claim 1, wherein the first and second substrates each include multiple levels of patterned conductive features and conductive vias.

7. The electronic device of claim 1, further comprising:
a first semiconductor die enclosed by the package structure and having a first circuit electrically coupled to the first substrate; and
a second semiconductor die enclosed by the package structure and having a second circuit electrically coupled to the second substrate.

8. The electronic device of claim 1, wherein the adhesive layer is non-conductive.

9. A transformer, comprising:
a first substrate including a first patterned conductive feature with multiple turns that form a first winding, and a first molded magnetic material that encloses a portion of the first patterned conductive feature;
an adhesive layer on a side of the first substrate; and
a second substrate including a second patterned conductive feature with multiple turns that form a second winding, and a second molded magnetic material that encloses a portion of the second patterned conductive feature, the second substrate extending on the adhesive layer to magnetically couple the first and second windings.

10. The transformer of claim 9, wherein the first and second substrates each include multiple levels of patterned conductive features and conductive vias.

11. The transformer of claim 10, wherein the adhesive layer is non-conductive.

12. The transformer of claim 10, wherein the first and second substrates and the adhesive layer are enclosed by a non-magnetic molded package structure.

13. The transformer of claim 9, wherein the adhesive layer is non-conductive.

14. The transformer of claim 13, wherein the first and second substrates and the adhesive layer are enclosed by a non-magnetic molded package structure.

15. The transformer of claim 9, wherein the first and second substrates and the adhesive layer are enclosed by a non-magnetic molded package structure.

16. A method of making an electronic device, the method comprising:
forming a first substrate including a first patterned conductive feature with multiple turns that form a first winding, and a first molded magnetic material that encloses a portion of the first patterned conductive feature;
forming a second substrate including a second patterned conductive feature with multiple turns that form a second winding, and a second molded magnetic material that encloses a portion of the second patterned conductive feature;
attaching a first side of the first substrate to a die attach pad using a first adhesive layer;
attaching a first side of the second substrate to a second side of the first substrate using a second adhesive layer; and
enclosing the first and second substrates and the first and second adhesive layers in a non-magnetic molded package structure.

17. The method of claim 16, wherein the first and second adhesive layers are non-conductive.

18. The method of claim 16, wherein the first and second substrates each include multiple levels of patterned conductive features and conductive vias.

19. The method of claim 18, wherein:
forming the first substrate includes:
performing a first plating process using a first plating mask to form the first patterned conductive feature,
performing a second plating process using a second plating mask to form a first via on a portion of the first patterned conductive feature, and
performing a first compression molding process that forms the first molded magnetic material to enclose the portion of the first patterned conductive feature; and
forming the second substrate includes;
performing a second plating process using a third plating mask to form the second patterned conductive feature,
performing a second plating process using a fourth plating mask to form a second via on a portion of the second patterned conductive feature, and
performing a second compression molding process that forms the second molded magnetic material to enclose the portion of the second patterned conductive feature.

20. The method of claim 16, wherein:
forming the first substrate includes:
performing a first plating process using a first plating mask to form the first patterned conductive feature,
performing a second plating process using a second plating mask to form a first via on a portion of the first patterned conductive feature, and
performing a first compression molding process that forms the first molded magnetic material to enclose the portion of the first patterned conductive feature; and
forming the second substrate includes;
performing a second plating process using a third plating mask to form the second patterned conductive feature,
performing a second plating process using a fourth plating mask to form a second via on a portion of the second patterned conductive feature, and
performing a second compression molding process that forms the second molded magnetic material to enclose the portion of the second patterned conductive feature.
